(19) United States
(12) Patent Application Publication
(10) Pub. No.: US 2022/0301816 A1
(43) Pub. Date: Sep. 22, 2022

(54) DRAWING METHOD, MASTER PLATE MANUFACTURING METHOD, AND DRAWING APPARATUS

(71) Applicant: Kioxia Corporation, Tokyo (JP)

(72) Inventor: Yoshinori KAGAWA, Shinagawa Tokyo (JP)

(73) Assignee: Kioxia Corporation, Tokyo (JP)

(21) Appl. No.: 17/475,034

(22) Filed: Sep. 14, 2021

(30) Foreign Application Priority Data
Mar. 18, 2021 (JP) 2021-045152

(51) Int. Cl. H01J 37/304; H01J 37/317; B29C 33/38; G03F 7/20; G03F 1/78

(52) U.S. Cl. CPC H01J 37/3045; H01J 37/3174; B29C 33/3842; G03F 7/70008; G03F 7/7055; G03F 1/78

(57) ABSTRACT

According to one embodiment, a drawing method includes acquiring a first arrangement information indicating an arrangement state of a stepped portion on a substrate. The method further includes acquiring a height information indicating a height of the stepped portion. The method further includes measuring a height of the substrate. The method further includes calculating a focus map indicating a distribution of beam focus values of an electron beam according to a drawing location on the substrate on a basis of the acquired first arrangement information and the height information, and the measured height of the substrate. The method further includes drawing a pattern on the substrate by an electron beam with a beam focus value determined on a basis of the calculated focus map.

### CROSS REFERENCE TO RELATED APPLICATIONS

This application is based upon and claims the benefit of priority from the prior Japanese Patent Application No. 2021-45152, filed on Mar. 18, 2021, the entire contents of which are incorporated herein by reference.

### FIELD

Embodiments of the present invention relate to a drawing method, a master plate manufacturing method, and a drawing apparatus.

### BACKGROUND

A master plate for a semiconductor process is sometimes created by drawing a pattern using an electron beam. In this case, it may be difficult to appropriately determine a beam focus value and draw a pattern with a high accuracy depending on surface profiles of a substrate for a master plate.

### BRIEF DESCRIPTION OF THE DRAWINGS

FIG. 1 is a diagram illustrating an example of a drawing apparatus according to a first embodiment;

FIG. 2A is a sectional view illustrating an example of a mask blank to which the drawing apparatus according to the first embodiment is applicable;

FIG. 2B is a sectional view illustrating an example of a template blank to which the drawing apparatus according to the first embodiment is applicable;

FIG. 2C is a sectional view illustrating another example of the mask blank to which the drawing apparatus according to the first embodiment is applicable;

FIG. 3 is a flowchart illustrating an example of a drawing method according to the first embodiment;

FIG. 4 is an explanatory diagram for explaining an acquiring process of surface profile data illustrated in the flowchart of FIG. 3;

FIG. 5 is an explanatory diagram for explaining a measuring process of a height of a substrate surface illustrated in the flowchart of FIG. 3 in the drawing method according to the first embodiment;

FIG. 6 is an explanatory diagram for explaining a calculating process of a height distribution illustrated in the flowchart of FIG. 3 in the drawing method according to the first embodiment;

FIG. 7 is an explanatory diagram for explaining a calculating process of a focus map illustrated in the flowchart of FIG. 3 in the drawing method according to the first embodiment;

FIG. 8 is an explanatory diagram for explaining a drawing process illustrated in the flowchart of FIG. 3 in the drawing method according to the first embodiment;

FIG. 9A is an explanatory diagram for explaining effects of the drawing method according to the first embodiment;

FIG. 9B is an explanatory diagram for explaining a first comparative example;

FIG. 9C is an explanatory diagram for explaining a second comparative example;

FIG. 10 is an explanatory diagram for explaining the measuring process of the height of the substrate surface illustrated in the flowchart of FIG. 3 in a drawing method according to a second embodiment;

FIG. 11 is an explanatory diagram for explaining the calculating process of the height distribution illustrated in the flowchart of FIG. 3 in the drawing method according to the second embodiment;

FIG. 12A is an explanatory diagram for explaining the acquiring process of the surface profile data illustrated in the flowchart of FIG. 3 in a drawing method according to a third embodiment;

FIG. 12B is an explanatory diagram for explaining an example in which an inclination angle and an inclination direction of each of slope portions are calculated in the drawing method according to the third embodiment;

FIG. 13A is a sectional view illustrating a manufacturing method of a photomask according to an embodiment;

FIG. 13B is a sectional view illustrating the manufacturing method of a photomask according to the embodiment, in continuation from FIG. 13A;

FIG. 13C is a sectional view illustrating the manufacturing method of a photomask according to the embodiment, in continuation from FIG. 13B;

FIG. 13D is a sectional view illustrating the manufacturing method of a photomask according to the embodiment, in continuation from FIG. 13C;

FIG. 13E is a sectional view illustrating the manufacturing method of a photomask according to the embodiment, in continuation from FIG. 13D;

FIG. 14A is a sectional view illustrating a manufacturing method of a template according to an embodiment;

FIG. 14B is a sectional view illustrating the manufacturing method of a template according to the embodiment, in continuation from FIG. 14A;

FIG. 14C is a sectional view illustrating the manufacturing method of a template according to an embodiment, in continuation from FIG. 14B;

FIG. 14D is a sectional view illustrating the manufacturing method of a template according to the embodiment, in continuation from FIG. 14C; and

FIG. 14E is a sectional view illustrating the manufacturing method of a template according to the embodiment, in continuation from FIG. 14D.

### DETAILED DESCRIPTION

According to one embodiment, a drawing method includes acquiring a first arrangement information indicating an arrangement state of a stepped portion on a substrate. The method further includes acquiring a height information indicating a height of the stepped portion. The method further includes measuring a height of the substrate. The method further includes calculating a focus map indicating a distribution of beam focus values of an electron beam according to a drawing location on the substrate on a basis of the acquired first arrangement information and the height information, and the measured height of the substrate. The method further includes drawing a pattern on the substrate by an electron beam with a beam focus value determined on a basis of the calculated focus map.

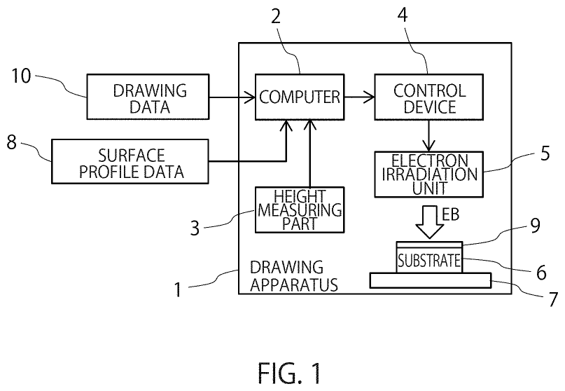

Embodiments of the present invention will be explained below with reference to the drawings. In FIGS. 1 to 14E, same or identical constituent elements are denoted by like reference characters and redundant explanations thereof are omitted.

### First Embodiment

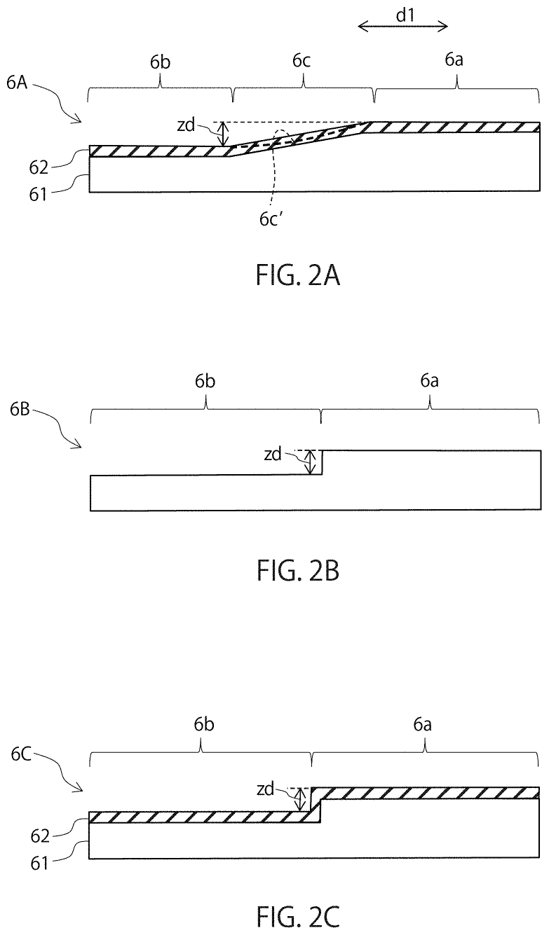

FIG. 1A is a diagram illustrating an example of a drawing apparatus 1 according to a first embodiment. The drawing apparatus 1 illustrated in FIG. 1 can be used, for example, to draw a pattern on a substrate 6 described later (that is, a resist film 9 on the substrate 6) with irradiation of an electron beam EB at the time of manufacturing a master plate to be used in a semiconductor process. Specific modes of the substrate 6 are not particularly limited as long as the substrate 6 is applicable to manufacturing of a master plate with irradiation of the electron beam EB. For example, the substrate 6 may be a mask blank 6A or 6C or a template blank 6B as will be described later with reference to FIGS. 2A to 2C.

The drawing apparatus 1 illustrated in FIG. 1 includes a computer 2, a height measuring part 3, a control device 4, an electron irradiation unit 5, and a stage 7. The electron irradiation unit 5 is placed in an electron optical lens barrel (not illustrated). The substrate 6 is mounted on the stage 7 in a vacuum chamber communicated with the electron optical lens barrel. The stage 7 can be moved by a driving device such as a motor, for example, in a horizontal direction (an X direction and a Y direction) and a vertical direction (a Z direction). The irradiation location of the election beam EB with respect to the substrate 6 on the stage 7 can be changed with movement of the stage 7.

Before the constituent parts of the drawing apparatus 1 are described in more detail, examples of the substrate 6 to which the drawing apparatus 1 is applicable are explained below. FIG. 2A is a sectional view illustrating an example of the mask blank 6A to which the drawing apparatus 1 according to the embodiment is applicable. FIG. 2B is a sectional view illustrating an example of the template blank 6B to which the drawing apparatus 1 according to the embodiment is applicable. FIG. 2C is a sectional view illustrating another example of the mask blank 6C to which the drawing apparatus 1 according to the embodiment is applicable. The mask blanks 6A and 6C are examples of the substrate 6 used in manufacturing of a photomask being a master plate for photolithography. The template blank 6B is an example of the substrate 6 used in manufacturing of a template being a master plate for nanoimprint lithography.

As illustrated in FIGS. 2A and 2C, each of the mask blanks 6A and 6C as the substrate 6 includes a translucent substrate 61, and a light shielding film 62 formed on the translucent substrate 61. The translucent substrate 61 may include, for example, quartz as a principal component. The light shielding film 62 may include, for example, a metal such as chrome (Cr) as a principal component. Meanwhile, the template blank 6B as the substrate 6 includes, for example, quartz as a principal component, thereby having a translucency as a whole as illustrated in FIG. 2B.

When there is a level difference or a slope on the surface of a processing target film formed on a device substrate (a wafer) for a semiconductor device, it is difficult to process the processing target film with a high accuracy in a case in which a photomask or a template having a uniformly flat surface is used. Specifically, in the case of photolithography using a photomask, it is difficult to focus exposure light onto a resist film on the processing target film, so that appropriately exposing the resist film on the processing target film to light becomes difficult. In the case of nanoimprint lithography using a template, it is difficult to transfer a pattern to a resist on a device substrate being a processing target film while appropriately pressing the template against the resist. As a result, formation of a circuit pattern on the processing target film with a desired accuracy becomes difficult. Therefore, with an objective of processing a processing target film including a level difference or a slope with a high accuracy, each of the surfaces of the substrates 6A to 6C for a photomask or a template has a surface profile matching the surface profile of the processing target film. Specifically, the surface of the mask blank 6A illustrated in FIG. 2A has a base portion 6a along an in-plane direction d1 (that is, being flat), a flat stepped portion 6b having a level difference zd (that is, a difference in the height) from the base portion 6a, and a slope portion 6c connecting the base portion 6a and the stepped portion 6b. When the mask blank 6A is mounted on the stage 7, the in-plane direction d1 corresponds to the horizontal direction. While the slope portion 6c illustrated in FIG. 2A is a linearly inclined plane, a slope portion 6c′ may be an inclined curved plane as indicated by sign 6c′ in FIG. 2A. Each of the surfaces of the template blank 6B illustrated in FIG. 2B and the mask blank 6C illustrated in FIG. 2C has the base portion 6a and the stepped portion 6b. The template blank 6B may have a slope portion.

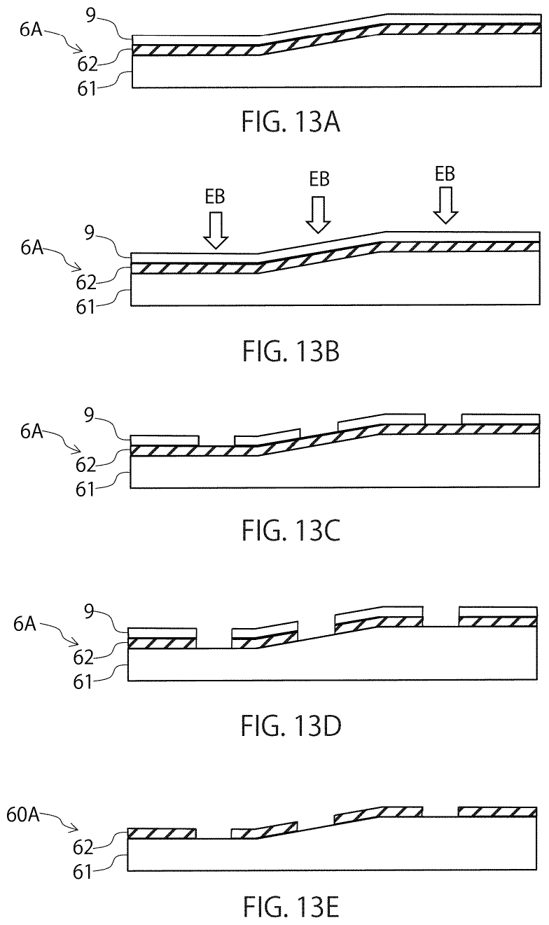

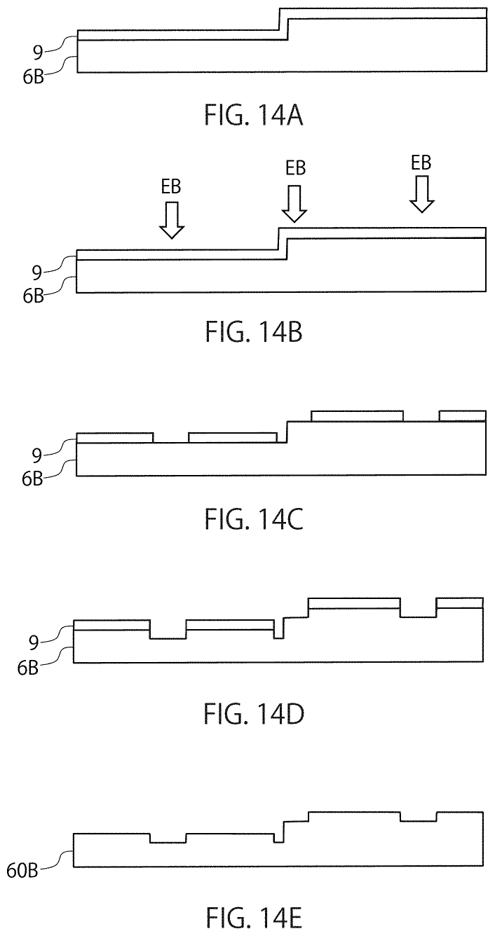

At the time of drawing a pattern on the substrate 6 to form a master plate (a photomask or a template), the resist film 9 is formed on the substrate 6. In FIG. 13A, the resist film 9 is formed on the mask blank 6A as an example of the substrate 6. In FIG. 14A, the resist film 9 is formed on the template blank 6B as an example of the substrate 6. The substrate 6 having the resist film 9 formed thereon is irradiated with the electron beam EB to draw a pattern on the resist film 9.

The substrate 6 having the resist film 9 formed thereon sags under its own weight. The drawing apparatus 1 according to the first embodiment is configured to draw a pattern in focus on the surface of the substrate 6 that has sagging and where there are stepped portions.

Specifically, as illustrated in FIG. 1, surface profile data 8 is input to the computer 2. The surface profile data 8 is data related to the surface profile of the substrate 6. The surface profile data 8 includes stepped portion arrangement information and stepped portion height information. The stepped portion arrangement information is information indicating arrangement states (for example, locations) of the stepped portions on the surface of the substrate 6. The stepped portion height information is information indicating the height of each of the stepped portions. The surface profile data 8 is, for example, data created by a computer different from the computer 2 on the basis of design data of the master plate. As illustrated in FIG. 1, drawing data 10 is also input to the computer 2. The drawing data 10 is data for drawing a pattern on the substrate 6 with irradiation of the electron beam EB. The drawing data 10 is, for example, data created by a computer different from the computer 2 on the basis of the design data of the master plate. The method of inputting the drawing data 10 and the surface profile data 8 to the computer 2 is not particularly limited and can be, for example, input through data communication or input through a storage medium. More details of the surface profile data 8 are explained in an embodiment of a drawing method, which will be described later.

The height measuring part 3 measures the height of the surface of the substrate 6. More specifically, the height measuring part 3 measures the height of the surface of the resist film 9 formed on the surface of the substrate 6. Further specifically, the height measuring part 3 measures the height of the surface of the substrate 6 at a plurality of places on the surface of the substrate 6. The height measuring part 3 outputs the measured heights of the surface of the substrate 6 to the computer 2. The height measuring part 3 may optically measure the heights of the surface of the substrate 6, for example, with a laser.

The computer 2 calculates a focus map indicating a distribution of focus values of an electron beam according to drawing locations of the substrate 6 on the basis of the stepped portion arrangement information and the stepped portion height information acquired from the surface profile data 8 and the measured heights of the surface of the substrate 6. The computer 2 outputs the calculated focus map to the control device 4. An example of calculation of the focus map by the computer is explained in the embodiment of the drawing method described later.

The control device 4 determines a beam focus value for each drawing unit (shot) on the substrate 6 on the basis of the focus map input from the computer 2. The control device 4 controls the electron irradiation unit 5 so as to draw a pattern on the substrate 6 with the electron beam of the determined beam focus value.

The electron irradiation unit 5 irradiates the electron beam EB of the beam focus value determined by the control device 4 to the substrate 6 to draw the pattern on the resist film 9 on the substrate 6. The electron irradiation unit 5 includes, for example, an electron gun that emits the electron beam EB, and an electron optical system (a deflector, an electromagnetic lens, or the like) that controls the trajectory of the emitted electron beam EB.

### (Drawing Method)

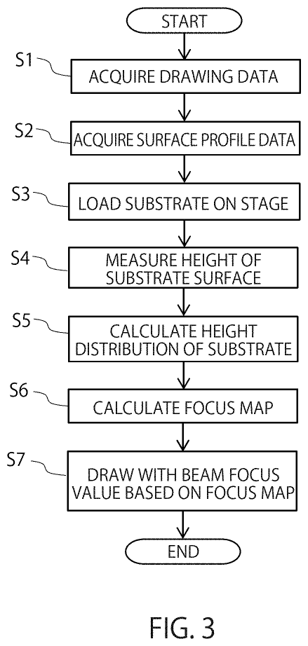

An embodiment of the drawing method to which the drawing apparatus 1 according to the first embodiment is applied is explained below. FIG. 3 is a flowchart illustrating an example of the drawing method according to the first embodiment.

As illustrated in FIG. 3, the computer 2 first acquires the drawing data 10 (Step S1). The drawing data 10 indicates a two-dimensional region corresponding to the surface of the substrate 6 and has a pattern defined in the region. The pattern on the drawing data 10 is drawn at a corresponding location (that is, coordinates) on the surface of the substrate 6.

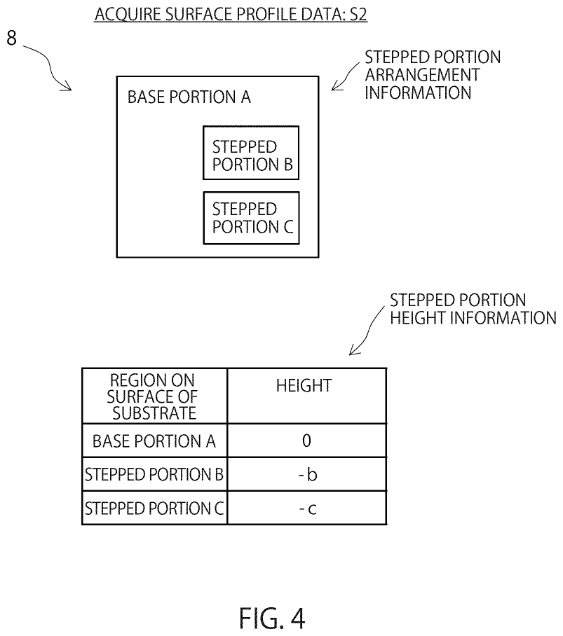

As illustrated in FIG. 3, the computer 2 also acquires the surface profile data 8 (Step S2). The acquisition of the surface profile data 8 may be performed before the acquisition of the drawing data 10 or may be performed at the same time as the acquisition of the drawing data 10. FIG. 4 is an explanatory diagram for explaining an example of an acquiring process of the surface profile data 8 illustrated in the flowchart of FIG. 3. As illustrated in FIG. 4, the surface profile data 8 includes at least the stepped portion arrangement information and the stepped portion height information. The stepped portion arrangement information is information indicating arrangement states (for example, locations) of stepped portions on the surface of the substrate 6. More specifically, the stepped portion arrangement information indicates a two-dimensional region corresponding to the drawing data and has the stepped portions defined in the region. The stepped portion height information is information indicating the height of each of the stepped portions. The stepped portion height information is information indicating the relative height with respect to an average height of a flat base portion not located in the stepped portions on the surface of the substrate as a reference (zero [μm]) for the height. In the example illustrated in FIG. 4, the stepped portions are concave steps lower in the level than the base portion. The stepped portions may be convex steps higher in the level than the base portion. The absolute value of the height of each of the stepped portions may be equal to or more than 0.1 [μm]. The surface profile data 8 may be data in a table format. An average height per unit area being 1 mm² as an example may be used as the height of each of the stepped portions.

After acquiring the drawing data 10 and the surface profile data 8, the drawing apparatus 1 loads the substrate 6 on the stage 7 as illustrated in FIG. 3 (Step S3). The substrate 6 already has the resist film 9 formed on the surface when loaded on the stage 7.

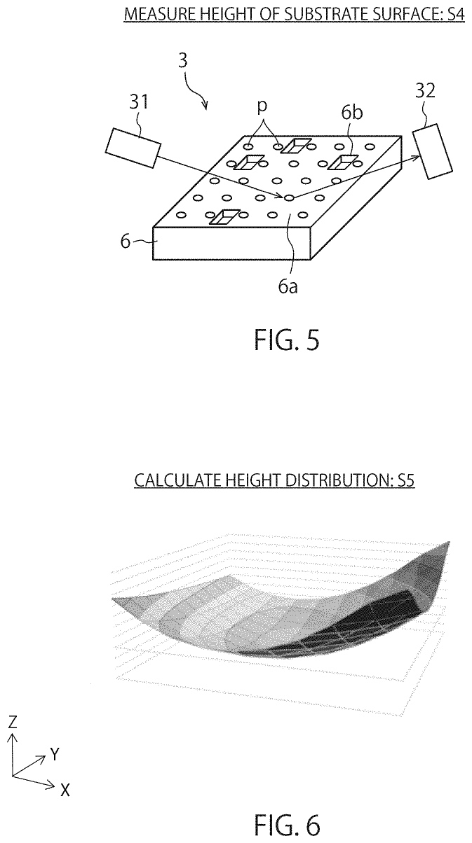

After the substrate 6 is loaded on the stage 7, the height measuring part 3 measures the height of the surface of the substrate 6, that is, the surface of the resist film 9 to perform drawing in focus on the surface of the substrate 6 including sagging (Step S4). FIG. 5 is an explanatory diagram for explaining a measuring process of the height of the substrate surface illustrated in the flowchart of FIG. 3 in the drawing method according to the first embodiment. Illustrations of the resist film 9 are omitted in FIG. 5. To calculate a height distribution of the substrate 6, the height measuring part 3 measures the height at a plurality of measuring points P on the surface of the substrate 6 as illustrated in FIG. 5. To prevent the stepped portions 6b from influencing the height distribution, the measuring points P are set on the base portion 6a being the surface of the substrate 6 except for the stepped portions 6b. The height measuring part 3 performs the measurement while setting the measuring points P only on the base portion 6a on the basis of the stepped portion arrangement information acquired by the computer 2. The height measuring part 3 measures the height of the surface of the substrate 6 at each of the measuring points P on the basis of a time from when light of a laser or the like is emitted from an emitter 31 (a light source) until when the light is reflected on the measuring point P and is received by a light receiver 32 (a sensor). To measure the height at each of the measuring points P, the height measuring part 3 drives the stage 7 in the X direction and the Y direction to sequentially move the measuring points P to the irradiation location of the light from the emitter 31.

After the heights of the surface of the substrate 6 are measured, the computer 2 calculates a height distribution indicating a distribution of the heights of the surface of the substrate 6 on the basis of the measured heights as illustrated in FIG. 3 (Step S5). The height distribution indicates degrees of the sagging of the substrate 6. FIG. 6 is an explanatory diagram for explaining a calculating process of the height distribution illustrated in the flowchart of FIG. 3 in the drawing method according to the first embodiment. The computer 2 calculates a height distribution on the entire surface of the substrate 6 using a high-degree polynomial based on the heights of the surface of the substrate 6 respectively measured at the measuring points P as the height distribution, as illustrated in FIG. 6. FIG. 6 illustrates a distribution of heights (Z) of the surface of the substrate 6 for each X coordinate and each Y coordinate.

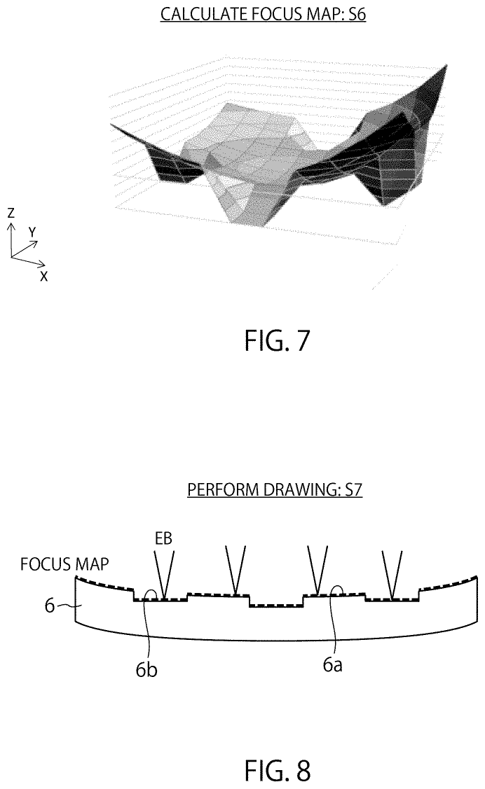

After calculating the height distribution, the computer 2 calculates a focus map by adding the stepped portion arrangement information and the stepped portion height information to the calculated height distribution as illustrated in FIG. 3 (Step S6). FIG. 7 is an explanatory diagram for explaining a calculating process of a focus map illustrated in the flowchart of FIG. 3 in the drawing method according to the first embodiment. In the example illustrated in FIG. 7, the computer 2 calculates a focus map by setting the height in each of ranges indicated by the stepped portion arrangement information in the height distribution to be lower by the height of the relevant concave step indicated by the stepped portion height information. When the stepped portions are convex steps, it suffices that the focus map is calculated by setting the height in each of ranges indicated by the stepped portion arrangement information in the height distribution to be higher by the height of the relevant convex step indicated by the stepped portion height information.

After the focus map is calculated, the control device 4 performs drawing with a beam focus value based on the focus map as illustrated in FIG. 3 (Step S7). That is, the control device 4 determines a beam focus value on the basis of the calculated focus map and draws a pattern on the substrate 6 with an electron beam of the determined beam focus value. FIG. 8 is an explanatory diagram for explaining a drawing process illustrated in the flowchart of FIG. 3 in the drawing method according to the first embodiment. As illustrated in FIG. 8, the electron beam EB of the beam focus value determined on the basis of the focus map calculated at Step S6 is in focus on the surface of the substrate 6 in both the base portion 6a and the stepped portions 6b.

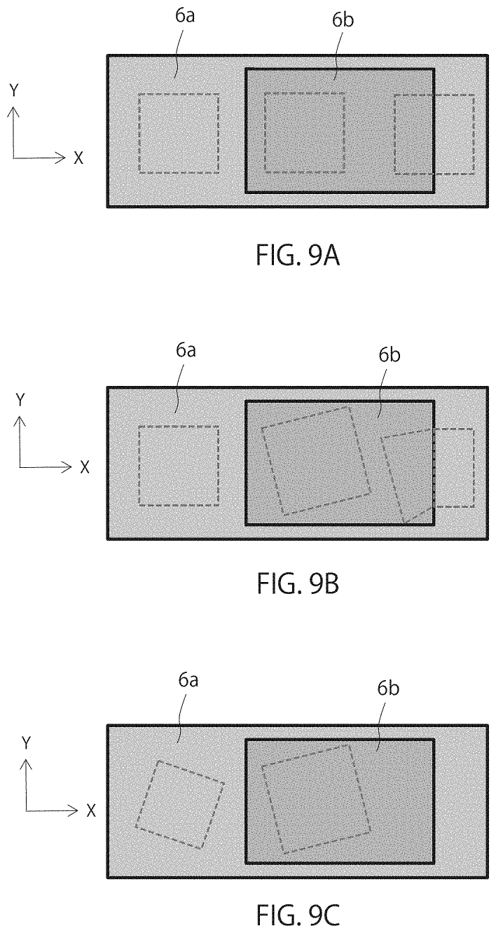

FIG. 9A is an explanatory diagram for explaining effects of the drawing method according to the first embodiment. FIG. 9B is an explanatory diagram for explaining a first comparative example. FIG. 9C is an explanatory diagram for explaining a second comparative example. In a case in which drawing is performed using a focus map calculated only on the basis of the heights of the surface of the substrate 6 measured except for the stepped portions, deviations of a rotational component and a magnification component occur in main deflection regions (regions that can be scanned with an electron beam) indicated by dashed rectangles in the stepped portion 6b having a different height from that of the base portion 6a of the substrate 6 as illustrated in FIG. 9B. Accordingly, the electron beam is defocused in the stepped portion 6b and the drawing accuracy of the pattern is deteriorated. In a case in which drawing is performed using a focus map calculated only on the basis of the heights of the surface of the substrate 6 measured in parts including the stepped portions, deviations of the rotational component and the magnification component occur in the main deflection regions both in the base portion 6a and the stepped portion 6b of the surface of the substrate 6 as illustrated in FIG. 9C. Accordingly, the electron beam is defocused in the stepped portion 6b and the drawing accuracy of the pattern is deteriorated.

In contrast thereto, with the drawing apparatus 1 according to the first embodiment, a pattern can be drawn with a high accuracy, irrespective of the surface profile of the substrate 6, by using a focus map calculated by adding the stepped portion arrangement information and the stepped portion height information to the height distribution based on the heights of the surface of the substrate 6 measured except for the stepped portions.

In drawing of a pattern, the beam stabilization time may be set longer in places where changes in the beam focus value are large than in places where changes in the beam focus value are small. Alternatively, the movement of the stage 7 having the substrate 6 mounted thereon may be set slower in the places where changes in the beam focus value are large than in the places where changes in the beam focus value are small. This enables drawing of a pattern to be appropriately performed in the places where changes in the beam focus value are large.

The drawing of a pattern may be sequentially performed starting from a place where changes in the beam focus value are small.

As described above, according to the first embodiment, a focus map is calculated on the basis of the stepped portion arrangement information, the stepped portion height information, and a measurement result of the surface height of the substrate 6, and drawing is performed with a beam focus value determined on the basis of the calculated focus map, so that a pattern can be drawn with a high accuracy irrespective of the surface profile of the substrate (the presence of stepped portions).

According to the first embodiment, a height distribution is calculated on the basis of the surface height of the substrate 6 measured except for the stepped portions, and a focus map is generated by adding the stepped portion arrangement information and the stepped portion height information to the calculated height distribution, so that a pattern can be drawn with a higher accuracy irrespective of the presence of stepped portions.

### Second Embodiment

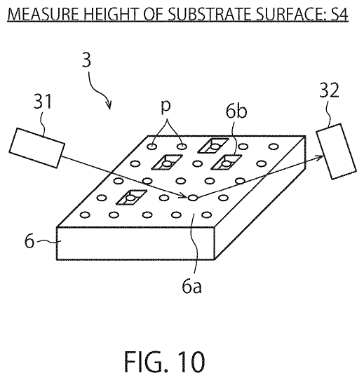

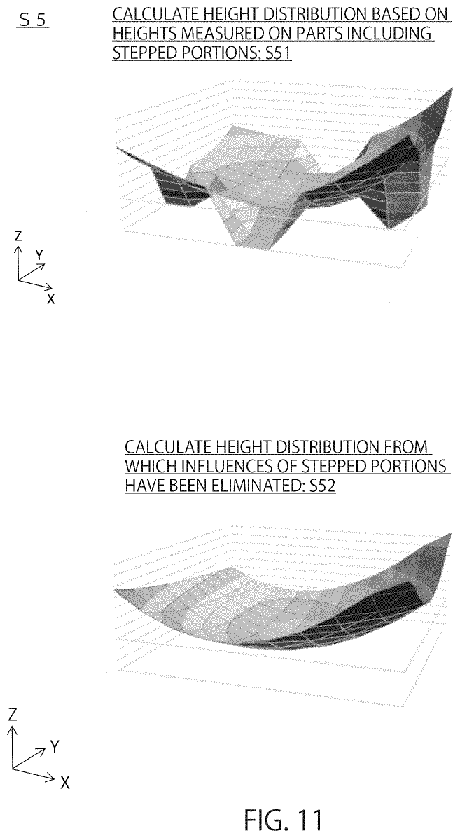

A second embodiment in which the calculation method of a focus map is different from that in the first embodiment is explained next with reference to FIGS. 10 and 11. FIG. 10 is an explanatory diagram for explaining the measuring process of the height of the substrate surface illustrated in the flowchart of FIG. 3 in a drawing method according to the second embodiment. FIG. 11 is an explanatory diagram for explaining the calculating process of the height distribution illustrated in the flowchart of FIG. 3 in the drawing method according to the second embodiment.

As explained with reference to FIG. 5, the height of the surface of the substrate 6 is measured while setting the measuring points P on the surface of the substrate 6 except for the stepped portions 6b, that is, only on the base portion 6a in the first embodiment. In contrast thereto, the measuring points P are set according to a predetermined method (for example, at equal intervals) in the second embodiment, without performing special setting of the measuring points P, such as purposely excluding the stepped portions 6b. As a result, some of the measuring points P are located on the stepped portions 6b. In the second embodiment, the computer 2 calculates a height distribution on the basis of the heights of the surface of the substrate 6 measured on parts including these stepped portions 6b. The calculated height distribution is a height distribution including influences of the stepped portions 6b as illustrated in FIG. 11 (Step S51). The height distribution including influences of the stepped portions 6b does not correctly represent the height distribution of the substrate 6.

In the second embodiment, the computer 2 calculates a height distribution that is obtained by eliminating the influences of the stepped portions 6b from the height distribution including the influences of the stepped portions 6b on the basis of the stepped portion arrangement information and the stepped portion height information (Step S52). For example, the height in a range indicated by the stepped portion arrangement information in the height distribution including the influences of the stepped portions 6b is increased by a height indicated by the stepped portion height information. Necessary profile complementation using a high-degree polynomial or the like may be further performed.

After the height distribution from which the influences of the stepped portions 6b has been eliminated is calculated, the processes identical to Step 6 and subsequent steps in FIG. 3 are performed.

According to the second embodiment, the height distribution from which the influences of the stepped portions 6b are eliminated later is calculated, and the stepped portion arrangement information and the stepped portion height information are added to the calculated height distribution to calculate a focus map, so that a pattern can be drawn with a high accuracy irrespective of the surface profile of the substrate 6 similarly in the first embodiment.

### Third Embodiment

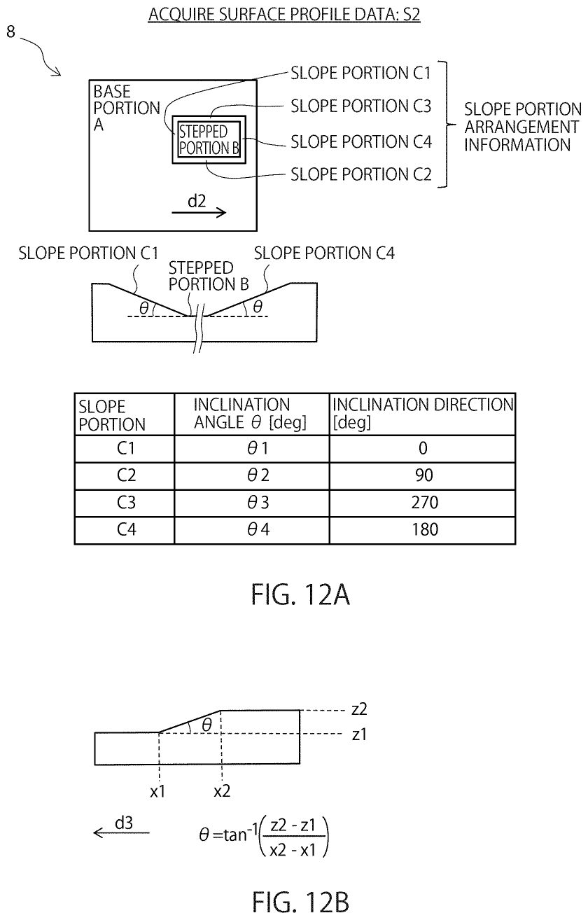

A third embodiment in which a focus map is calculated further considering slope portions is explained next with reference to FIGS. 12A and 12B. FIG. 12A is an explanatory diagram for explaining the acquiring process of the surface profile data illustrated in the flowchart of FIG. 3 in a drawing method according to the third embodiment. FIG. 12B is an explanatory diagram for explaining an example in which an inclination angle and an inclination direction of each of slope portions are calculated in the drawing method according to the third embodiment.

In the third embodiment, the surface profile data 8 includes slope portion arrangement information, inclination angle information, and inclination direction information. The slope portion arrangement information is information indicating arrangement states of the slope portions on the surface of the substrate 6. The inclination angle information is information indicating an inclination angle θ of each of the slope portions as illustrated in FIG. 12A. The inclination direction information is information indicating the direction of each of the slope portions. More specifically, in an example illustrated in FIG. 12A, the inclination direction information is information representing a direction on two dimensions in which the height of each of the slope portions decreases, using an angle formed with a reference direction d2 on the two dimensions. For example, since the direction of a slope portion Cl illustrated in FIG. 12A on the two dimensions in which the height of the slope portion Cl decreases corresponds to the reference direction d2, the inclination direction is zero [degrees]. Meanwhile, since the direction of a slope portion C4 illustrated in FIG. 12A on the two dimensions in which the height of the slope portion C4 decreases is opposite to the reference direction d2, the inclination direction is 180 [degrees].

In the third embodiment, the computer 2 calculates a focus map by further adding the slope portion arrangement information, the inclination angle information, and the inclination direction information in addition to the stepped portion arrangement information and the stepped portion height information to the height distribution. Specifically, the computer 2 calculates the focus map by setting the height in a range indicated by the stepped portion arrangement information in the height distribution to be lower by the height indicated by the stepped portion height information, and setting the height in a range indicated by the slope portion arrangement information to be lower by the height indicated by the inclination angle information and the inclination direction information.

FIG. 12B is an explanatory diagram for explaining an example of calculation of the inclination angle and the inclination direction of each of the slope portions in the drawing method according to the third embodiment. When the surface profile data 8 does not include the inclination angle information and the inclination direction information, the computer 2 can calculate the inclination angle and the inclination direction of each of the slope portions on the basis of the slope portion arrangement information and the stepped portion height information, and calculate a focus map using the calculated inclination angle and inclination direction. For example, the inclination angle θ and an inclination direction d3 may be calculated on the basis of the X coordinate (x1) and the Z coordinate (z1) of a lower end of a slope portion, and the X coordinate (x2) and the Z coordinate (z2) of an upper end of the slope portion indicated by the slope portion arrangement information and the height information as illustrated in FIG. 12B. In the example illustrated in FIG. 12B, the inclination angle θ is the arctangent (tan⁻¹) of the slope (z2−z1)/(x2−x1) of a linear function connecting the coordinates of two points of the lower end (x1, z1) of the slope portion and the upper end (x2, z2) thereof. In the example illustrated in FIG. 12B, the inclination direction d3 is a direction from x2 toward x1, in which the Z value of the linear function decreases.

According to the third embodiment, with calculation of a focus map further considering the slope portions in addition to the stepped portions, a pattern can be drawn with a high accuracy irrespective of whether there are stepped portions and slope portions.

### (Master Plate Manufacturing Method)

The drawing methods according to the embodiments explained with reference to FIGS. 3 to 12B can be used for manufacturing of a master plate. An embodiment of a manufacturing method of a photomask, and an embodiment of a manufacturing method of a template are sequentially explained below as master plate manufacturing methods to which the drawing method according to any of the embodiments is applied.

FIG. 13A is a sectional view illustrating a manufacturing method of a photomask according to the embodiment. As illustrated in FIG. 13A, in manufacturing of a photomask, the resist film 9 is first formed on the mask blank 6A explained with reference to FIG. 2A. The formation of the resist film 9 includes coating of the resist film 9 and pre-baking after the coating. In the example illustrated in FIG. 13A, the resist film 9 is a positive film. The resist film 9 may be a negative film.

FIG. 13B is a sectional view illustrating the manufacturing method of a photomask according to the embodiment, in continuation from FIG. 13A. After the resist film 9 is formed, the electron beam EB with a beam focus value determined using the drawing method according to the embodiment is irradiated by the drawing apparatus 1 as illustrated in FIG. 13B. Accordingly, the resist film 9 at portions to which the electron beam EB is irradiated is exposed to light.

FIG. 13C is a sectional view illustrating the manufacturing method of a photomask according to the embodiment, in continuation from FIG. 13B. After the resist film 9 is exposed to light and the exposed resist film 9 is post-baked, the resist film 9 is developed as illustrated in FIG. 13C. The development of the resist film 9 is performed by a wet process using a chemical. The portions of the resist film 9 exposed to light are removed by the development and the light shielding film 62 is partially exposed at locations where the resist film 9 has been removed.

FIG. 13D is a sectional view illustrating the manufacturing method of a photomask according to the embodiment, in continuation from FIG. 13C. After the resist film 9 is developed, the light shielding film 62 is etched (that is, processed) using the developed resist film 9 as a mask. The etching is performed by a dry process.

FIG. 13E is a sectional view illustrating the manufacturing method of a photomask according to the embodiment, in continuation from FIG. 13D. After the light shielding film 62 is etched, the resist film 9 is removed as illustrated in FIG. 13E. Accordingly, a photomask 60A is obtained.

FIGS. 14A to 14E are sectional views illustrating a manufacturing method of a template 60B according to the embodiment. As illustrated in FIGS. 14A to 14E, the manufacturing method of the template 60B is basically the same as the manufacturing method of the photomask 60A. The manufacturing method of the template 60B is different from the manufacturing method of the photomask 60A in that a target processed by etching is not the light shielding film 62 but the template blank 6B.

With the manufacturing method of the photomask 60A or the template 60B according to the embodiment, drawing can be performed with a high accuracy irrespective of the surface profile of the substrate. Due to applying the photomask 60A or the template 60B having a pattern drawn with a high accuracy to a semiconductor process, a pattern of an accurate dimension can be formed on a device substrate having level differences or slopes on the surface, and a semiconductor device can be appropriately manufactured.

At least a part of the computer 2 illustrated in FIG. 1 can be constituted by hardware or software. When it is constituted by software, the computer 2 can be configured such that a program for realizing at least a part of the functions of the computer 2 is stored in a recording medium such as a flexible disk or a CD-ROM, and the program is read and executed by a computer. The recording medium is not limited to a detachable device such as a magnetic disk or an optical disk, and can be a fixed recording medium such as a hard disk device or a memory. Further, a program for realizing at least a part of the functions of the computer 2 can be distributed via a communication line (including wireless communication) such as the Internet. Furthermore, the program can be distributed in an encrypted, modulated, or compressed state via a wired communication line or a wireless communication line such as the Internet, or the program is distributed as it is stored in a recording medium.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

1. A drawing method comprising:
acquiring a first arrangement information indicating an arrangement state of a stepped portion on a substrate;
acquiring a height information indicating a height of the stepped portion;
measuring a height of the substrate;
calculating a focus map indicating a distribution of beam focus values of an electron beam according to a drawing location on the substrate on a basis of the acquired first arrangement information and the height information, and the measured height of the substrate; and
drawing a pattern on the substrate by an electron beam with a beam focus value determined on a basis of the calculated focus map.

2. The method of claim 1, wherein
the measuring of the height of the substrate is performed except for the stepped portion,
the calculating of the focus map includes
calculating a height distribution indicating a distribution of the height of the substrate on a basis of the height measured except for the stepped portion, and
adding the first arrangement information and the height information to the calculated height distribution.

3. The method of claim 1, wherein
the measuring of the height of the substrate is performed with the stepped portion,
the calculating of the focus map includes
calculating a first height distribution indicating a distribution of the height of the substrate on a basis of the height measured with the stepped portions,
calculating a second height distribution by eliminating influences of the height of the stepped portion from the calculated first height distribution, and
adding the first arrangement information and the height information to the calculated second height distribution.

4. The method of claim 1, further comprising
acquiring a second arrangement information indicating an arrangement state of a slope portion of the substrate, and
calculating an inclination angle and an inclination direction of the slope portion on a basis of the acquired second arrangement information and the height information.

5. The method of claim 2, further comprising
acquiring a second arrangement information indicating an arrangement state of a slope portion of the substrate, and
calculating an inclination angle and an inclination direction of the slope portion on a basis of the acquired second arrangement information and the height information.

6. The method of claim 3, further comprising acquiring a second arrangement information indicating an arrangement state of a slope portion of the substrate, and
calculating an inclination angle and an inclination direction of the slope portion on a basis of the acquired second arrangement information and the height information.

7. The method of claim 1, further comprising
acquiring inclination angle information indicating an inclination angle of the slope portion on the substrate, and
acquiring inclination direction information indicating an inclination direction of the slope portion.

8. The method of claim 2, further comprising
acquiring inclination angle information indicating an inclination angle of the slope portion on the substrate, and
acquiring inclination direction information indicating an inclination direction of the slope portion.

9. The method of claim 3, further comprising
acquiring inclination angle information indicating an inclination angle of the slope portion on the substrate, and
acquiring inclination direction information indicating an inclination direction of the slope portion.

10. The method of claim 1, wherein the drawing of the pattern includes setting a beam stabilization time to be longer in a place where a change in the beam focus value is large than in a place where a change in the beam focus value is small.

11. The method of claim 1, wherein the drawing of the pattern includes setting movement of a stage having the substrate mounted thereon to be slower in a place where a change in the beam focus value is larger than in a place where a change in the beam focus value is small.

12. The method of claim 1, wherein the drawing of the pattern is sequentially performed starting from a place where a change of the beam focus value is small.

13. The method of claim 4, wherein the slope portion includes an inclined plane.

14. The method of claim 4, wherein the slope portion includes an inclined curved plane.

15. A master plate manufacturing method comprising:
acquiring a first arrangement information indicating an arrangement state of a stepped portion on a substrate;
acquiring a height information indicating a height of the stepped portion;
forming a resist film on the substrate,
measuring a height of the substrate which is measuring of a height of a surface of the resist film;
calculating a focus map indicating a distribution of beam focus values of an electron beam according to a drawing location on the substrate on a basis of the acquired first arrangement information and the height information, and the measured height of the substrate;
drawing a pattern on the substrate by an electron beam with a beam focus value determined on a basis of the calculated focus map, the drawing of the pattern being performed to the resist film;
processing the substrate using the resist film developed as a mask; and
removing the resist film from the processed substrate.

16. The method of claim 15, wherein the master plate is a photomask.

17. The method of claim 15, wherein the master plate is a template for imprint lithography.

18. A drawing apparatus comprising:
an acquiring part configured to acquire a first arrangement information indicating an arrangement state of a stepped portion on a substrate, and a height information indicating a height of the stepped portion;
a measuring part configured to measure a height of the substrate;
a calculator configured to calculate a focus map indicating a distribution of beam focus values of an electron beam according to drawing locations on the substrate on a basis of the acquired first arrangement information and the height information, and the measured height of the substrate; and
a drawing part configured to draw a pattern on the substrate by an electron beam with a beam focus value determined on a basis of the calculated focus map.
